(19) United States
(12) Patent Application Publication
(10) Pub. No.: US 2016/0165747 A1
(43) Pub. Date: Jun. 9, 2016

(54) DISPLAY DEVICE AND TELEVISION RECEIVER

(71) Applicant: SHARP KABUSHIKI KAISHA, Osaka-shi, Osaka (JP)

(72) Inventors: Hiroki IWATA, Osaka-shi (JP); Toshihiro YAMAMICHI, Osaka-shi (JP)

(73) Assignee: SHARP KABUSHIKI KAISHA, Osaka-shi, Osaka (JP)

(21) Appl. No.: 14/409,962

(22) PCT Filed: Jun. 18, 2013
(86) PCT No.: PCT/JP2013/066673

§ 371 Date: Dec. 19, 2014

(30) Foreign Application Priority Data
Jun. 22, 2012 (JP) 2012-141231
Mar. 15, 2013 (JP) 2013-053708

(51) Int. Cl. H05K 7/18; H04N 5/44; H04N 5/64

(52) U.S. Cl. CPC H05K 7/186; H04N 5/64; H04N 5/44

(57) ABSTRACT

Provided are a display device capable of suppressing occurrence of defective products due to fastening defect of screws, having excellent productivity and workability, achieving narrowing of frame and thinning of set thickness with excellent appearance quality, and manufacturing at a low cost, as well as a television receiver including the display device. A TV receiver includes a display module, and horizontal frames which cover long side peripheral end part of a front surface of the display module. A first plate part and a second plate part forming each side of L-shaped connectors are provided with a plurality of female screws. The horizontal frame includes an end edge covering part which covers long side end edge part of the display module, and a side covering part which covers a side part thereof, and a protruding part which protrudes inwardly of the side covering part. The protruding part is provided with a plurality of screw insertion holes. With the connector aligned to end portions of the horizontal frame and the vertical frame, screws are inserted into the screw insertion holes, and screwed to the female screws of the first plate part, and thereby the horizontal frame and the vertical frame are connected to each other.

### CROSS-REFERENCE TO RELATED APPLICATIONS

This application is the national phase under 35 U.S.C. §371 of PCT International Application No. PCT/JP2013/66673 which has an International filing date of Jun. 18, 2013 and designated the United States of America.

### BACKGROUND

1. Technical Field

The present invention relates to a display device, in which a rectangular frame covering the peripheral edge part of a display unit is divided into four frame members such that end portions of the adjacent frame members are connected to each other by connectors, and a television receiver including the display device.

2. Description of Related Art

Recently, the size of a thin type television receiver (hereinafter, referred to as a TV receiver) including a liquid crystal display, or the like is becoming larger, and the number of models thereof such as 52, 60 and 70 inch display sizes is increasing as well. In this case, as the display size is becoming larger, and a cabinet (frame body) forming the appearance of the television is also becoming larger, but a desire to make the outer size as small as possible is also strong. Therefore, narrow frame products in which a frame portion of a rectangular front cabinet located around a display screen is made narrow are also on sale.

In general, the front cabinet covering the peripheral edge part of a display unit is an integrated frame and is manufactured by a mold. The cost of the mold is in direct proportion to the size of the front cabinet, and in large models, the cost of the mold becomes higher. Further, in a case of expanding the large models in a plurality of variations, the mold costs are increased by the number of models. Accordingly, a TV receiver in which the front cabinet is divided into four frame members of top, bottom, left and right, and the end portions of each frame member are connected to each other by L-shaped connectors at four corners has been developed (for example, Japanese Patent Laid-open Publication No. 2002-190997, etc.).

In Japanese Patent Laid-open Publication No. 2002-190997, plate-shaped frame members are provided with ribs (protrusions) on an inner surface thereof, and L-shaped connectors abutting the ribs are provided with through holes in each side thereof, such that tapping screws passing through the through holes are screwed to the ribs so as to connect two frame members to each other.

FIG. 1 is a partial longitudinal sectional view illustrating a conventional TV receiver 69 having a front cabinet in which four frame members are connected to each other by connectors. In the drawing, a rear cabinet is not illustrated.

The TV receiver 69 includes a display module 2, a front cabinet covering the peripheral edge part of the display module 2, a front bezel 14, and a rear bezel 15. The front cabinet includes a horizontal frame 65 and a vertical frame (not illustrated).

The display module 2 includes a liquid crystal display panel (hereinafter, referred to as a display panel) 21, three optical sheets 22, a diffusion plate 23, a reflection sheet 24, and a chassis 25.

The reflection sheet 24 has a flat plate part, an inclination part rising from a peripheral edge of the flat plate part, and an edge part protruding from an end edge of the inclination part.

The chassis 25 is formed in a box shape by molding a metal plate, and has a flat plate part which is formed in a rectangular shape, a frame part which is formed so as to vertically rise from a peripheral edge of the flat plate part, and an edge part which is disposed so as to protrude from an end of the frame part to an outside of the box shape substantially parallel to the flat plate part. A plurality of LED substrates (not illustrated) are disposed on the flat plate part of the chassis 25 side by side in the short side direction.

The rear bezel 15 is formed in a frame shape to cover a peripheral edge part of the optical sheet 22, and integrally holds the optical sheet 22, the diffusion plate 23, the reflection sheet 24, and the edge part of the chassis 25. The front bezel 14 is formed in a frame shape with a size capable of housing the rear bezel 15, and covers a peripheral portion of the display panel 21, and further integrally holds the optical sheet 22, the diffusion plate 23, the reflection sheet 24, and the chassis 25 which are integrally held by the rear bezel 15, and the display panel 21.

The horizontal frame 65 of the front cabinet includes an end edge covering part 65a which covers an end edge part of a front surface of the display module 2, a side covering part 65b which is continuously arranged orthogonal to the end edge covering part 65a and covers a side part of the display module 2, and a cylindrical projection (boss) 65c provided on a corner portion side of the end edge covering part 65a. The projection 65c is provided with a female screw 65d therein.

A connector 68 formed in an L shape is provided with a plurality of screw insertion holes 68a therein.

With the vertical frame of the front cabinet arranged on a rear side of the paper surface of FIG. 1, and the connector 68 aligned to end portions of the horizontal frame 65 and the vertical frame, a screw 18 is inserted into the screw insertion hole 68a, and screwed to the female screw 65d of the projection 65c, and thereby the horizontal frame 65 and the vertical frame are connected to each other.

### SUMMARY

Recently, in the above-described TV receiver having the front cabinet in which four frame members are connected to each other by connectors, using the frame member which uses extruded materials with inexpensive mold costs has been increased for reducing the mold costs. Specifically, aluminum, or the like is used as the extruded material.

As described above, the frame members are connected to each other through the connectors, and stainless steel, or the like is often used as a material of the connector, and in order to fix the frame members with the connectors, screw holes (female screws) are formed in the frame members so as to be fastened with screws. However, since the frame members are made of a soft metal material such as aluminum, or the like which is likely to cause screw damage, defective products often occur due to fastening failure or the like. When defective products occur, a new frame member is required for replacing the same, and it has been a factor to which F cost (cost for the occurrence of the defective products) is significantly increased.

As a measure for this, when a torque of the screw is set to be weak, since the torque of the screw is different from the other parts, it is necessary to manage the torque of the connecting portions and the torque of the other parts separately, and thereby there are problems in which productivity and workability may be deteriorated. In addition, when making the screw damage less likely to occur by increasing the length of the screw, there is a problem that a set thickness of the TV receiver may be increased.

Further, in the conventional connecting structure, since the thick projection 65c, or the like is required for fixing the screw to the frame member made of aluminum, the cross-section of the frame member may become non-uniform so as to cause deterioration in appearance of product and an increase in unit costs. That is, in the conventional connecting structure, the root of the projection 65c becomes thick, and flow of the material is not uniform during forming of the frame member, thereby there is a problem that warping and sink (thick part is recessed) may easily occur in the frame member, and quality control may become difficult so as to cause a decrease in productivity.

In consideration of the above-described circumstances, it is an object of the present invention to provide a display device in which, when a rectangular frame covering peripheral edge parts of a display unit is divided into four frame members, and end portions of the frame members adjacent at four corners of a rectangle are connected to each other by connectors, occurrence of defective products due to fastening failure of screws may be suppressed, and it is possible to have excellent productivity and workability, achieve narrowing of frame and thinning of set thickness with excellent appearance quality, and manufacture at a low cost, as well as a television receiver including the display device.

According to an aspect of the present invention, there is provided a display device which includes a display unit, and a rectangular frame covering the peripheral edge part of the display unit, wherein the frame has a plurality of frame members which form a plurality of sides of a rectangle, and a plurality of connectors which connect adjacent end portions of the frame members, wherein the connector is provided with female screws for screwing the frame members.

In the display device according to the present invention, the connector has two plate parts extending in respective longitudinal directions of the frame members to be connected, and the plate parts are provided with the female screws.

In the display device according to the present invention, the frame member has an end edge covering part which covers an end edge part of a front surface of the display unit for displaying an image, and a side covering part which covers a side part of the display unit, the side covering part has a protruding part which protrudes substantially parallel to the end edge covering part on the inward side, the protruding part is provided with an insertion hole into which a screw is inserted, and the plate part is configured to be inserted between the protruding part and the end edge covering part so that the protruding part is screwed to the plate part.

In the display device according to the present invention, the plate part has a U-shaped cross-section in the short side direction.

In the display device according to the present invention, the plate part is provided with a projection on its plane, and the protruding part is provided with a locking part for locking the projection.

In the display device according to the present invention, the female screw is formed so as not to penetrate the connector.

In the display device according to the present invention, the female screw is provided in a recessed part formed by deep drawing from a front side of the connector.

According to another aspect of the present invention, there is provided a television receiver including: the above-described display device; and a receiving part which receives a television broadcast, wherein the display device is configured to display an image based on the television broadcast received by the receiving part.

According to the present invention, since the female screws are provided in the connector using a harder metal than the frame, occurrence of defective products due to fastening defect such as screw damage, or the like may be suppressed, and even when replacement of the connector is required due to occurrence of the screw damage, only the connector with the damaged screw may be replaced, and therefore replacement costs and F costs may be reduced. In addition, torque management of the connecting portion may be made common with the torque management of other general parts made of metal, and therefore productivity and workability may be improved. Further, a length of the screw may be shortened, and the set thickness may be reduced by arranging the connector closer to the frame side. Furthermore, since thickening measures of the frame are not required, it is possible to achieve narrowing of the frame.

In addition, the frame may have a uniform cross-section shape, and since the productivity of the frame is improved and the volume thereof is decreased, material costs may be reduced, and thereby overall cost may be reduced. Further, poor appearance such as impairment of appearance caused by that the shape of a thick portion is reflected, or the like may be suppressed, while having excellent appearance quality.

Furthermore, in a case that the female screw is designed so as not to penetrate the connector, or is provided in a recessed part formed by deep drawing from the front side of the connector, when a screw is fastened to the female screw, chips generated between the screw and the connector may not dropped to the rear side of the connector. Therefore, a decrease in optical quality caused by the chips entering between the liquid crystal display panel and the optical member may be prevented.

The above and further objects and features will more fully be apparent from the following detailed description with accompanying drawings.

### BRIEF DESCRIPTION OF THE SEVERAL VIEWS OF THE DRAWINGS

FIG. 1 is a partial longitudinal sectional view illustrating a conventional TV receiver;

FIG. 2 is a perspective view illustrating an appearance of a TV receiver according to Embodiment 1 of the present invention;

FIG. 3 is a rear view illustrating a state in which a rear cabinet of the TV receiver according to Embodiment 1 of the present invention is removed;

FIG. 4 is a partially enlarged view of FIG. 3;

FIG. 5 is a partial longitudinal sectional view illustrating a state in which the rear cabinet is removed;

FIG. 6 is a rear view illustrating a front cabinet;

FIG. 7 is a partially enlarged view of FIG. 6;

FIG. 8 is a perspective view of a portion of FIG. 7;

FIG. 9 is a perspective view illustrating a connector;

FIG. 10 is a plan view illustrating the connector;

FIG. 11 is a side view illustrating the connector;

FIG. 12 is a perspective view illustrating a state in which a second plate part of the connector is inserted between a protruding part and an end edge covering part of a vertical frame;

FIG. 13 is a perspective view illustrating a state in which the protruding part is screwed to the second plate part;

FIG. 14 is a perspective view illustrating a state in which a first plate part of the connector is inserted between a protruding part and an end edge covering part of a horizontal frame;

FIG. 15 is a perspective view illustrating a state in which the protruding part is screwed to the first plate part;

FIG. 16 is a partial longitudinal sectional view illustrating a TV receiver according to Embodiment 2 of the present invention;

FIG. 17 is a perspective view illustrating a state in which a second plate part of a connector according to Embodiment 3 of the present invention is inserted between a protruding part and an end edge covering part of the vertical frame;

FIG. 18 is a partial cross-sectional view of the second plate part;

FIG. 19 is a perspective view illustrating a state in which the protruding part is screwed to the second plate part;

FIG. 20 is a perspective view illustrating a state in which a second plate part of a connector according to Embodiment 4 of the present invention is inserted between a protruding part and an end edge covering part of the vertical frame;

FIG. 21 is a partial cross-sectional view of the second plate part;

FIG. 22 is a perspective view illustrating the connector as seen from a back side thereof;

FIG. 23 is a perspective view illustrating a state in which the protruding part is screwed to the second plate part.

### DETAILED DESCRIPTION

Hereinafter, the present invention will be described in detail with reference to the accompanying drawings illustrating the embodiments thereof.

### Embodiment 1

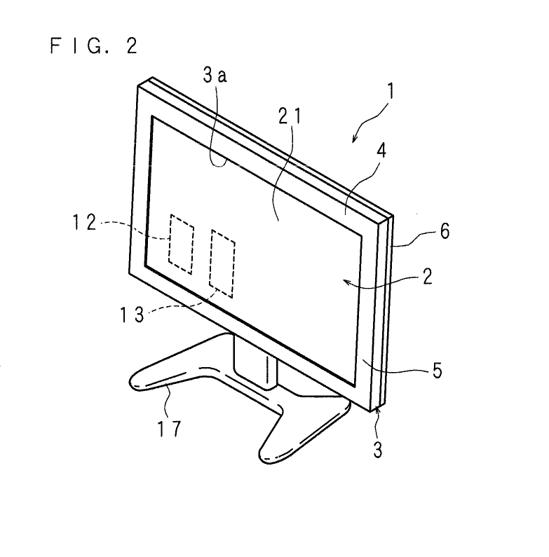

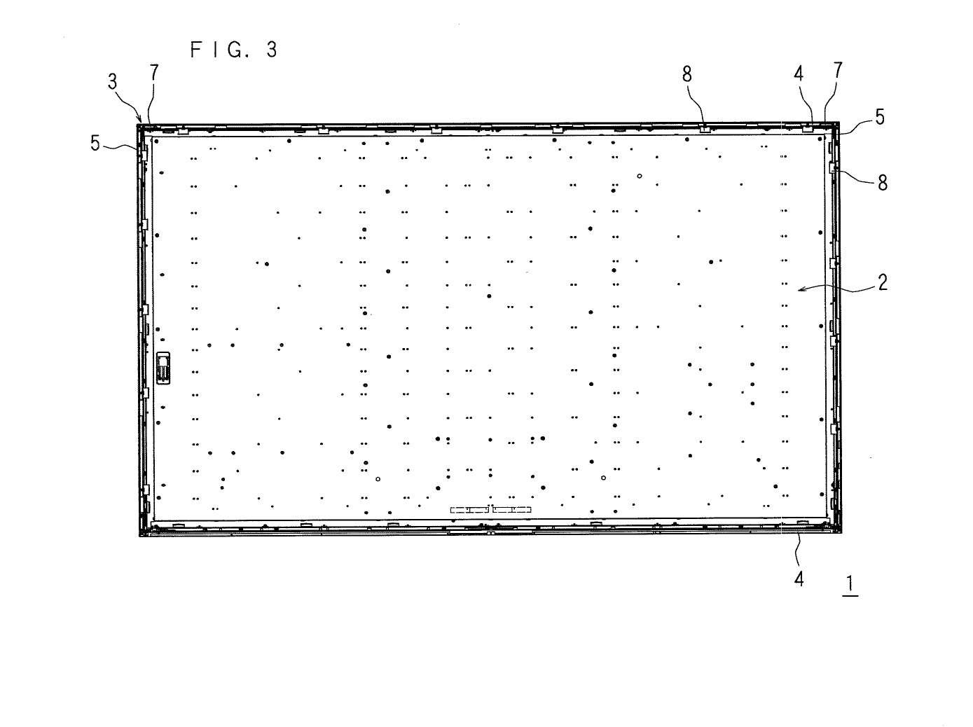

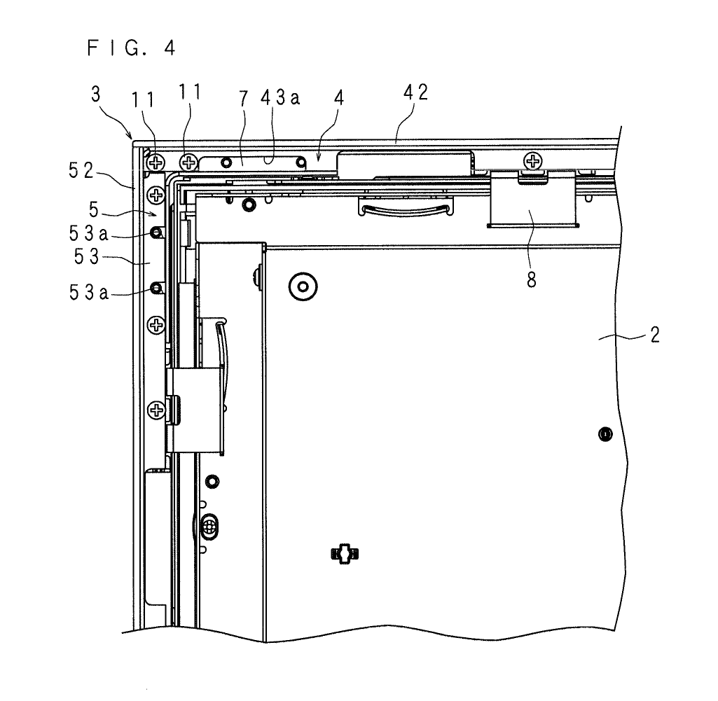

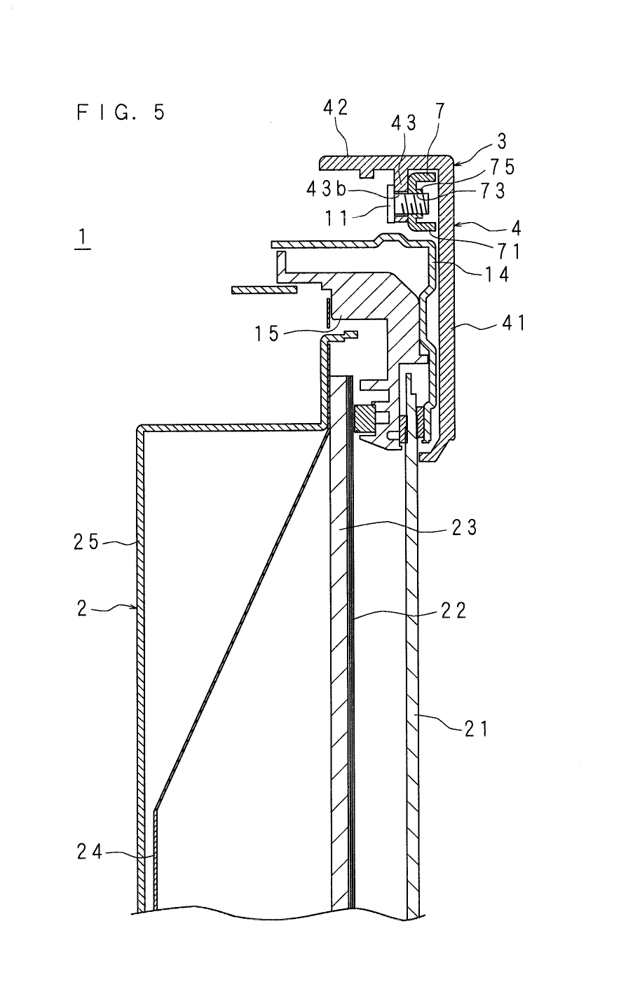

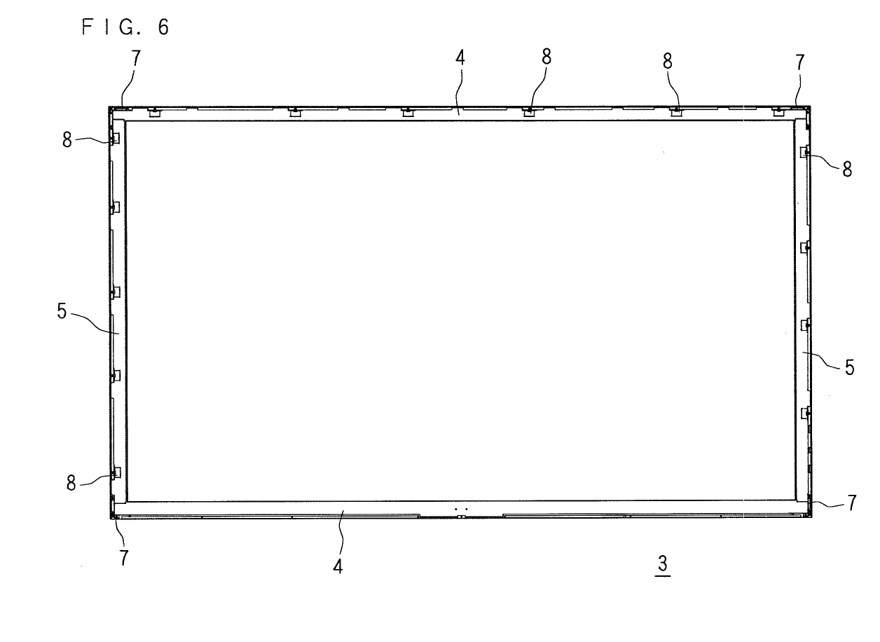

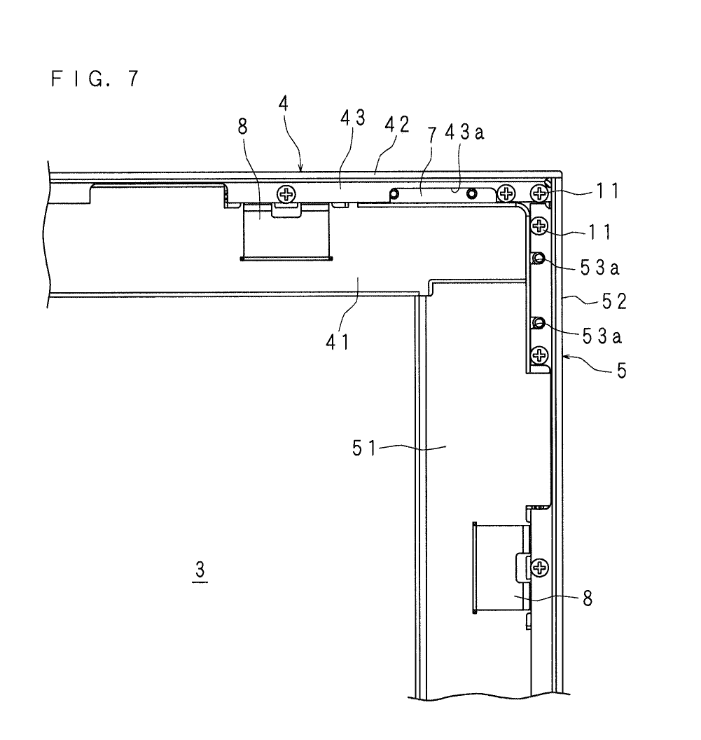

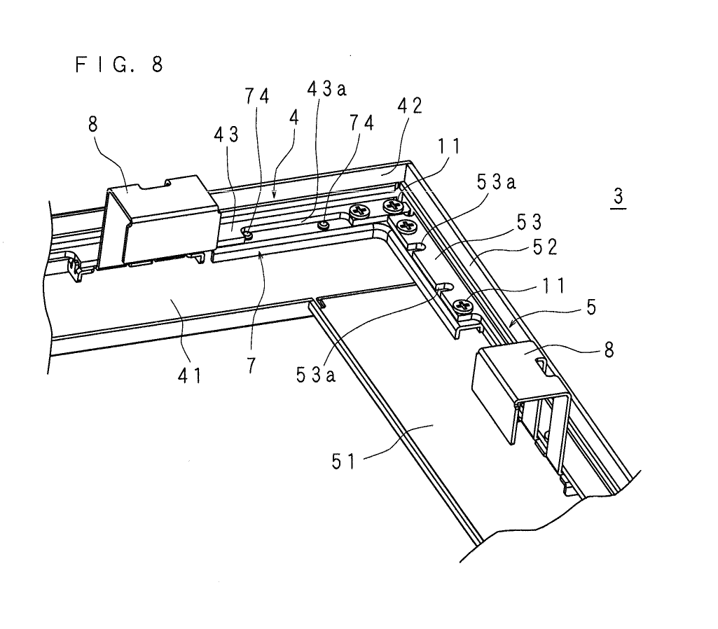

FIG. 2 is a perspective view illustrating a front appearance of a television receiver 1 (hereinafter, referred to as a TV receiver) according to Embodiment 1 of the present invention, FIG. 3 is a rear view illustrating a state in which a rear cabinet of the TV receiver 1 according to Embodiment 1 of the present invention is removed, FIG. 4 is a partially enlarged view of FIG. 3, FIG. 5 is a partial longitudinal sectional view illustrating a state in which the rear cabinet is removed, FIG. 6 is a rear view illustrating a front cabinet, FIG. 7 is a partially enlarged view of FIG. 6, and FIG. 8 is a perspective view of a portion of FIG. 7.

The TV receiver 1 includes a laterally long display module 2 for displaying an image thereon, a tuner 12 which is disposed in the display module 2 to receive a broadcast wave from an antenna (not illustrated), and a decoder 13 which is disposed in the display module 2 to decode the encoded broadcast wave. In the TV receiver 1, the decoder 13 decodes the broadcast wave received by the tuner 12, and the display module 2 displays an image based on decoded information. The TV receiver 1 is provided with a stand 17 for supporting the TV receiver 1 at a lower side thereof.

The display module 2 includes a laterally long rectangular display panel 21 having a display surface on a front side thereof. The display panel 21 is housed longitudinally between a front cabinet 3 and a rear cabinet 6 disposed longitudinally in front and back respectively. The front cabinet 3 is a rectangular frame for covering peripheral edge parts of the display panel 21, and has a rectangular opening 3a in the center thereof. The front cabinet 3 is made of aluminum, for example. The rear cabinet 6 is formed in a rectangular tray shape with the front side open, and is made of electro-galvanized steel plate, for example. Further, the front cabinet 3 and the rear cabinet 6 may be made of other material as well.

The vertical and lateral dimensions of the front cabinet 3 and the rear cabinet 6 are substantially the same, and peripheral edge portions thereof face each other. The vertical and lateral dimensions of the display panel 21 are slightly larger than those of the opening 3a of the front cabinet 3, and the peripheral edge part of the display panel 21 faces an inner edge part of the front cabinet 3.

As illustrated in FIG. 3, the front cabinet 3 includes a pair of horizontal frames 4 which cover long side end edge parts of a front surface and side parts of the display module 2, a pair of vertical frames 5 which covers short side end edge parts of the front surface and side parts of the display module 2, and four connectors 7 which connect end portions of the adjacent horizontal frame 4 and the vertical frame 5. The connector 7 may be made of stainless steel, for example.

As illustrated in FIGS. 6 to 8, the horizontal frame 4 includes an end edge covering part 41 which extends in a plate shape so as to be along a long side of the display module 2, a side covering part 42 which is continuously arranged so as to be orthogonal to the end edge covering part 41, and extends in the plate shape so as to be along the side part of the display module 2, and a plate-shaped protruding part 43 which protrudes inwardly from the side covering part 42 near the end edge covering part 41 substantially parallel to the end edge covering part 41. A width of the end edge covering part 41 is larger than the width of the side covering part 42, and as an example, a width of the protruding part 43 is substantially ¼ of the width of end edge covering part 41. A notch (locking part) 43a having a prescribed length is provided in an inner end edge part of the protruding part 43 at a longitudinal direction connecting side thereof.

The vertical frame 5 includes an end edge covering part 51 which extends in a plate shape along a short side of the display module 2, a side covering part 52 which is continuously arranged so as to be orthogonal to the end edge covering part 51, and extends in the plate shape along the side part of the display module 2, and a plate-shaped protruding part 53 which protrudes inwardly from the side covering part 52 near the end edge covering part 51 substantially parallel to the end edge covering part 51. A width of the end edge covering part 51 is larger than the width of the side covering part 52, and as an example, a width of the protruding part 53 is substantially ¼ of the width of end edge covering part 51. Narrow notches 53a and 53a are provided at two places in an inner end edge part of the protruding part 53 at a longitudinal direction connecting side thereof.

While keeping each side of the connector 7 formed in a substantially L shape close to the inner side (front side of the TV receiver 1) of end portions of the respective protruding parts 43 and 53, and a projection 74 of the connector 7 to be described below is locked to the notches 43a, 53a and 53a, the horizontal frame 4 and the vertical frame 5 are connected to each other by screwing with screws 11. A detailed attaching structure of the connector 7 will be described below.

As illustrated in FIGS. 3 to 5, the display module 2 includes the display panel 21, three optical sheets 22, a diffusion plate 23, a reflection sheet 24, and a chassis 25. The optical sheets 22, the diffusion plate 23, the reflection sheet 24, and the chassis 25 form a backlight unit.

The reflection sheet 24 is a white sheet, and for example, may be made of a resin material having an optical reflectivity such as polyethylene terephthalate (PET), polycarbonate (PC) or the like. The reflection sheet 24 has a flat plate part, an inclination part rising from a peripheral edge of the flat plate part, and an edge part protruding from an end edge of the inclination part. The flat plate part is formed in a rectangular shape.

The chassis 25 is for example, formed in a box shape by molding a metal plate, and has a flat plate part which is formed in a rectangular shape, a frame part which is formed so as to vertically rise from a peripheral edge of the flat plate part, and an edge part which is disposed so as to protrude from an end of the frame part to an outside of the box shape substantially parallel to the flat plate part.

A plurality of LED substrates (not illustrated) are disposed on the flat plate part of the chassis 25 side by side in a lateral direction of the flat plate part. Each LED substrate includes a substrate, LEDs, and lenses. The substrate is formed in an elongated rectangular shape. A plurality of LEDs are mounted on the substrate in a row in the longitudinal direction.

Herein, a light source of the backlight unit is not limited to the LED, and it may be a cold-cathode tube or the like. In addition, the backlight unit is not limited to a direct type, and it may be an edge light type.

The display panel 21 has a liquid crystal layer, a pair of glass substrates, and polarizing plates. The pair of glass substrates is bonded to each other through a seal material, and the liquid crystal layer is held therebetween. In addition, the polarizing plates are respectively disposed on a surface of a side opposite to the liquid crystal layer side of the pair of glass substrates.

The diffusion plate 23 is formed in a relatively thick rectangular plate shape and has a main surface which faces the display panel 21 side, a rear surface which is an opposite surface of the main surface and faces the chassis 25, a pair of long sides, and a pair of short sides. In addition, light introduced into the diffusion plate 23 from the rear side is diffused and emitted toward the display panel 21 side from the main surface of the diffusion plate 23.

The optical sheets 22 are a sheet group including a diffusion sheet, prism sheet, DBEF sheet (reflection type polarizing sheet), or the like, and are placed on the main surface of the diffusion plate 23. In addition, collection, etc. of the light emitted from the main surface of the diffusion plate 23 is performed by the optical sheets 22.

A rear bezel 15 is formed in a frame shape to cover a peripheral edge part of the optical sheet 22, and integrally holds the optical sheet 22, the diffusion plate 23, the reflection sheet 24, and the chassis 25. A front bezel 14 is formed in a frame shape with a size capable of housing the rear bezel 15, and covers a peripheral portion of the display panel 21, and further integrally holds the optical sheet 22, the diffusion plate 23, the reflection sheet 24, and the chassis 25 which are integrally held by the rear bezel 15, and the display panel 21.

In addition, as described above, the horizontal frame 4 and the vertical frame 5 are connected to each other by the connector 7, and a plurality of fixing members 8, which are locked to an edge part of the chassis 25 at a plurality of places and have U-shaped cross-section, are screwed to the upper horizontal frame 4 and both vertical frames 5 at a plurality of places, and thereby the chassis 25 is fixed to the front cabinet 3.

Hereinafter, the attaching structure of the connector 7 will be described in detail.

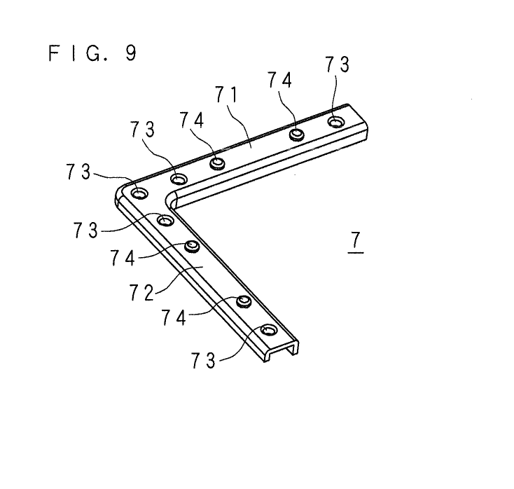

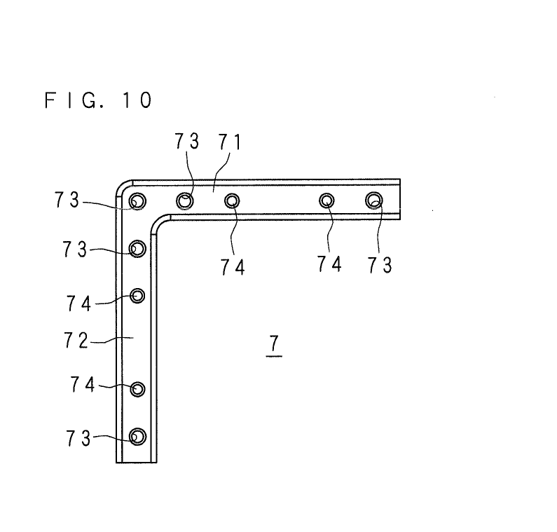

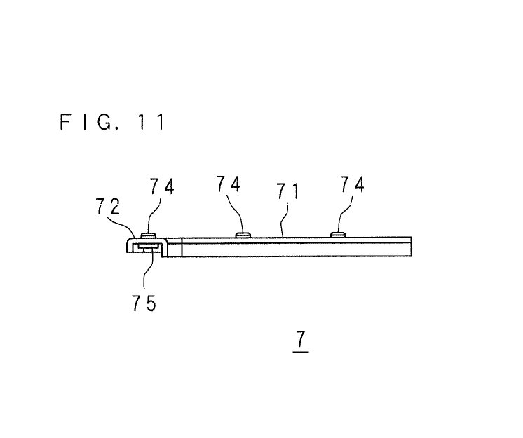

FIG. 9 is a perspective view illustrating the connector 7, FIG. 10 is a plan view illustrating the connector 7, and FIG. 11 is a side view illustrating the connector 7.

The connector 7 is formed in an L shape as described above. A first plate part 71 and a second plate part 72 forming each side of L shape are formed in a narrow plate shape, and provided with short legs elongating from opposite end portions thereof in the short side direction. That is, the cross-section thereof is formed in a U shape in the short side direction. Thereby, the strength of the connector 7 may be secured, and the connector 7 may be lightened.

The connector 7 is provided with a female screw 73 formed at a corner of the L shape. Further, the first plate part 71 and the second plate part 72 are provided with female screws 73 and 73 respectively formed at portions slightly near the tip end from the corner female screw 73, and female screws 73 and 73 respectively formed at the tip end portions. The female screws 73 are formed by performing screw hole processing from front surfaces of the first plate part 71 and the second plate part 72, after low height cylindrical screw detent parts 75 are formed on the rear surface of the first plate part 71 and the second plate part 72 by burring.

The first plate part 71 and the second plate part 72 are provided with small disc-shaped projections 74 and 74 respectively formed at portions slightly near the tip end from the female screws 73 adjacent to the corner female screw 73. Similarly, the first plate part 71 and the second plate part 72 are provided with projections 74 and 74 respectively formed at portions slightly near the corner from the tip end side female screws 73.

In the first plate part 71 and the second plate part 72 of the connector 7, distances from the corner female screw 73 to the female screw 73, the projection 74, the projection 74, and the female screw 73, which are sequentially formed toward the tip end sides, are the same.

Hereinafter, a connecting method of the horizontal frame 4 and the vertical frame 5 by the connector 7 will be described.

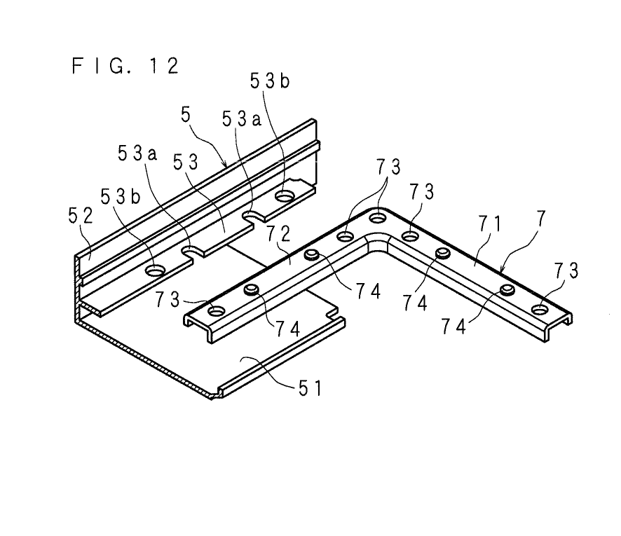

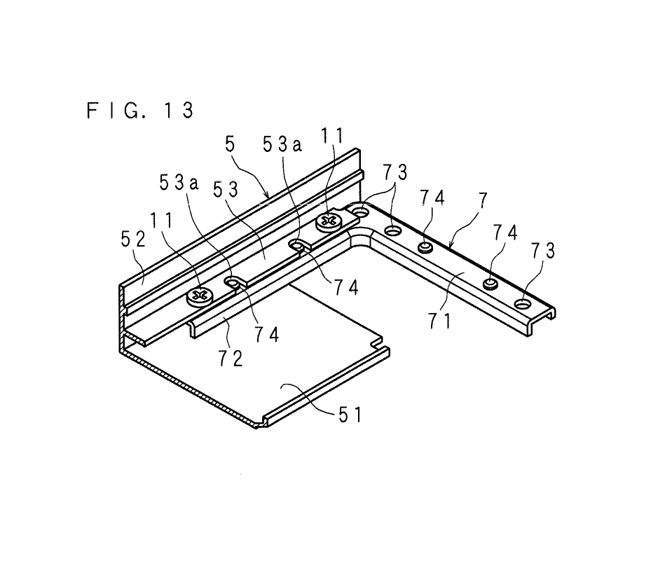

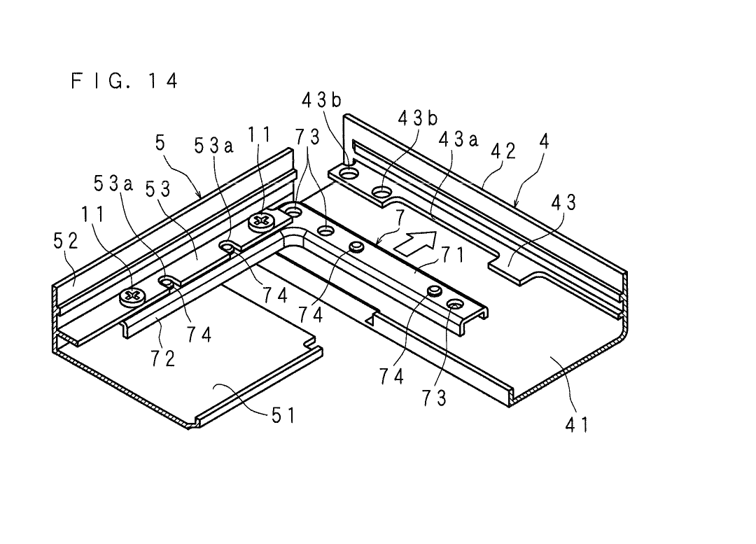

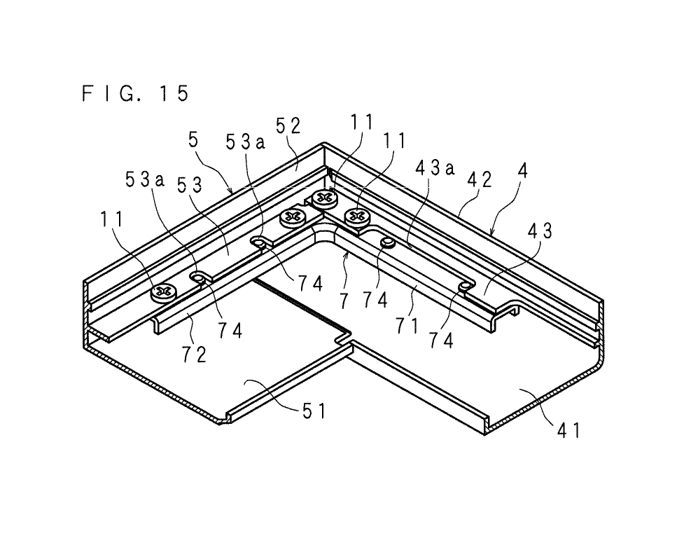

FIG. 12 is a perspective view illustrating a state in which the second plate part 72 of the connector 7 is inserted between the protruding part 53 and the end edge covering part 51 of the vertical frame 5, FIG. 13 is a perspective view illustrating a state in which the protruding part 53 is screwed to the second plate part 72, FIG. 14 is a perspective view illustrating a state in which the first plate part 71 of the connector 7 is inserted between the protruding part 43 and the end edge covering part 41 of the horizontal frame 4, and FIG. 15 is a perspective view illustrating a state in which the protruding part 43 is screwed to the first plate part 71.

As illustrated in FIG. 12, the protruding part 53 is provided with screw insertion holes 53b and 53b which are respectively formed at a slightly corner side from the corner side notch 53a and at a slightly lower side from the lower side notch 53a.

First, the second plate part 72 is inserted between the protruding part 53 and the end edge covering part 51 in such a manner that the projections 74 and 74 of the second plate part 72 of the connector 7 are engaged into the notches 53a and 53a of the protruding part 53.

Then, with the projections 74 and 74 locked to the notches 53a and 53a to be fixed (positioned) thereto, the screws 11 and 11 are inserted into the screw insertion holes 53b and 53b, and screwed to two female screws 73 and 73 of the second plate part 72, and thereby the vertical frame 5 and the connector 7 are connected to each other.

As illustrated in FIG. 14, the protruding part 43 of the horizontal frame 4 is provided with screw insertion holes 43b and 43b at a corner side and at a slightly tip end side.

With the tip end side projection 74 of the first plate part 71 of the connector 7 abutting a side wall of a side separated from the corner of the notch 43a of the protruding part 43, and the corner side projection 74 abutting a side wall of the notch 43a in the longitudinal direction, the first plate part 71 is inserted between the protruding part 43 and the end edge covering part 41.

Then, with the projections 74 locked to the notches 43a to be fixed (positioned) thereto, the screws 11 and 11 are inserted into the screw insertion holes 43b and 43b, and screwed to the female screws 73 and 73 adjacent to the corner and thereto, and thereby the horizontal frame 4 and the connector 7 are connected to each other. By this, the horizontal frame 4 and the vertical frame 5 are connected to each other.

As illustrated in FIG. 5, the screw 11 is inserted into the screw insertion hole 43b, and fastened to the female screw 73 provided in the first plate part 71 and the screw detent part 75.

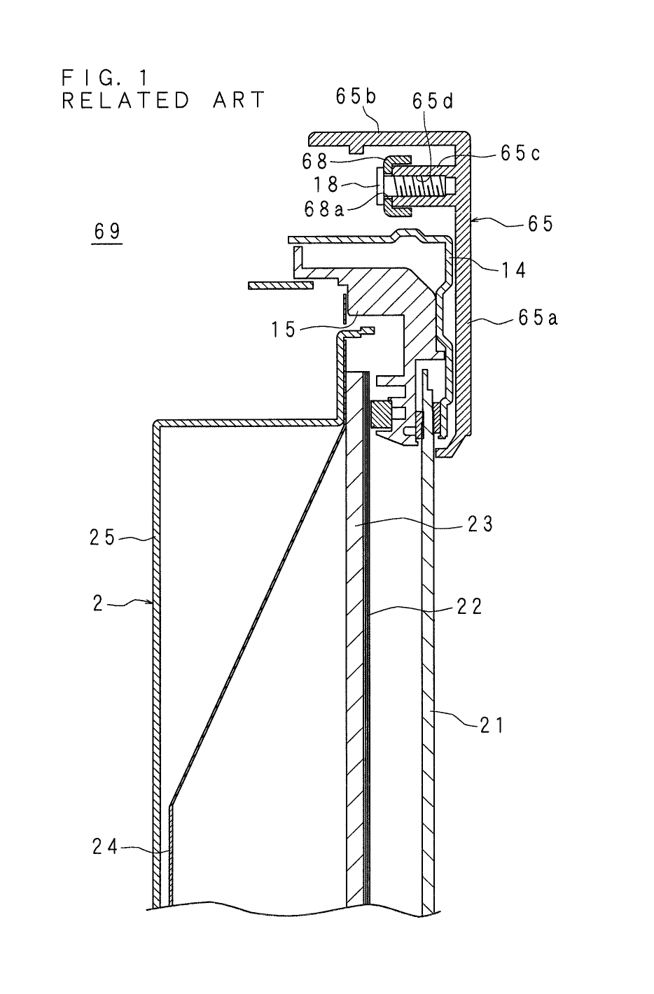

It can be seen that, in the connecting structure of the conventional TV receiver 69 illustrated in FIG. 1, it is necessary to increase the length of the screw 18, whereas in the connecting structure of the present embodiment illustrated in FIG. 5, it is possible to decrease the length of the screw 11. In the conventional connection structure, since the screw 18 is screwed to the end edge covering part 65a of the horizontal frame 65 made of a soft metal such as aluminum, or the like, it is easy to cause screw damage, and thereby the protruded length of the projection 65c is increased, and the length of the screw 18 is also increased. Compared to this, in the present embodiment, since the screw 11 is screwed to the connector 7 made of a hard metal such as stainless steel, or the like, it is difficult to cause screw damage. Since the length of the screw 11 may be a length that the length of the screw detent part 75 or a slightly protruding length therefrom is added to the thickness of the protruding part 43 and the first plate part 71, it may be shortened as a whole. In the present embodiment, since the length of the screw 11 may be shortened, and the connector 7 is disposed adjacent to the end edge covering parts 41 and 51 side, the set thickness of the TV receiver 1 may be decreased. In addition, even when the screw damage has occurred, it may be dealt with by replacing only the connector 7 with the damaged screw, and the replacement costs may be reduced.

In addition, torque management of the connecting portion may be unified with the torque management of other general parts made of metal, and therefore productivity and workability may be improved.

Further, in the conventional connecting structure, the root of the projection 65c, or the like becomes thick, and flow of the material is not uniform during forming of the horizontal frame 65 and the vertical frame, thereby there is a problem that warping and sinkage are easily occur in the horizontal frame 65 and the vertical frame, and quality control becomes difficult to cause a decrease in productivity, whereas in the connecting structure of the present embodiment, since a thick part is not formed on the horizontal frame 4 and the vertical frame 5, and the thickness may be uniform. Therefore, the above-described problems are eliminated, and productivity may be improved, and thereby it is possible to obtain the front cabinet 3 with stable quality. Furthermore, since the material costs may also be kept low, and costs of the horizontal frame 4 and the vertical frame 5 may be kept low as well as providing an improvement in yield, it is possible to reduce the overall cost of the TV receiver 1.

Further, in the conventional structure, in order to avoid thickening of the horizontal frame 65, a clearance between the side covering part 65b and the projection 65c is required for molding, and a clearance for reinforcing the connector 68 and ensuring a clearance with the display module 2 is required. However, in the present embodiment, since these clearances are no longer required, it is possible to narrow the width of the end edge covering part 65a, and thereby it is possible to narrow the frame of the TV receiver.

Also, in the present embodiment, since in the first plate part 71 and the second plate part 72 of the connector 7, the distances from the corner female screw 73 to the female screw 73, the projection 74, the projection 74, and the female screw 73, which are sequentially formed toward the tip end sides, are the same, it is possible to use the connector 7 at any corner of the front cabinet 3.

Meanwhile, the configuration of the connector 7 is not limited to the configuration of the present embodiment. The female screws 73 may be formed in the connector 7, not the front cabinet 3, and the displacement of the female screws 73 and the projections 74 is not limited to the above-described cases, and the connector 7 is not limited to the case of being formed in the narrow flat plate shape.

### Embodiment 2

A TV receiver 60 according to Embodiment 2 of the present invention has the same configuration as the TV receiver 1 according to Embodiment 1, except that the structure of a horizontal frame 64 and a vertical frame is different therefrom.

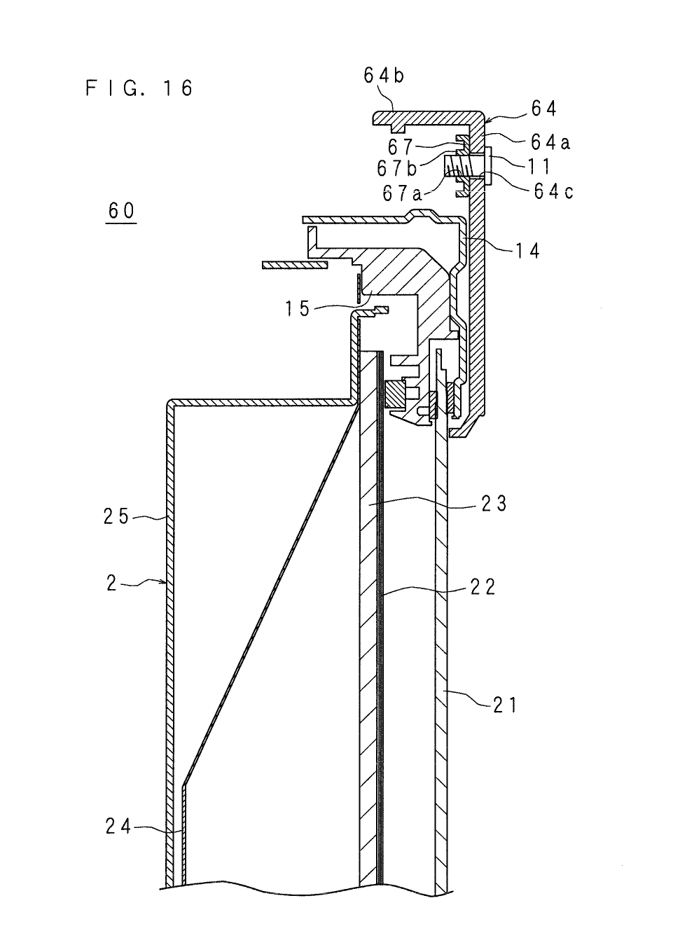

FIG. 16 is a partial longitudinal sectional view illustrating the TV receiver 60 according to Embodiment 2 of the present invention. In the drawings, the same parts as FIG. 5 will be denoted by the same reference numerals, and will not be described.

The horizontal frame 64 of the TV receiver 60 includes an end edge covering part 64a which extends in a plate shape so as to be along a long side of the display module 2, a side covering part 64b which is continuously arranged so as to be orthogonal to the end edge covering part 64a, and extends in the plate shape so as to be along the side part of the display module 2. Unlike the horizontal frame 4 according to Embodiment 1, the side covering part 64b is not provided with the protruding part. The vertical frame of the TV receiver 60 has the same configuration as the horizontal frame 64.

The end edge covering part 64a is provided with a plurality of screw insertion holes 64c near the side covering part 64b.

A connector 67 of the TV receiver 60 is formed in an L shape, and each side (plate part) of the L shape of the connector 67 has a U-shaped cross-section in the short side direction. A plurality of female screws 67a are provided in each side, by forming a plurality of screw detent parts 67b in a rear surface of each side of the L shape by burring, and then performing screw hole processing from the front surface of each side.

With the vertical frame of the front cabinet arranged on a rear side of the paper surface of FIG. 16, the connector 67 aligned to end portions of the horizontal frame 64 and the vertical frame, and the front surface of the connector 67 abutting the rear surface of the end edge covering part 64a, the screw 11 is inserted into the screw insertion hole 64c, and screwed to the female screw 67a of the connector 67, and thereby the horizontal frame 64 and the vertical frame are connected to each other.

In the present embodiment, since the female screws 67a are provided in the connector 67 using a harder metal than the horizontal frame 64 and the vertical frame, occurrence of defective products due to fastening defect such as screw damage, or the like may be suppressed, and even when replacement of the connector is required due to occurrence of the screw damage, only the connector 67 with the damaged screw may be replaced, and therefore replacement costs and F costs may be reduced. In addition, torque management of the connecting portion may be unified with the torque management of other general parts made of metal, and therefore productivity and workability may be improved. In addition, the horizontal frame 64 and the vertical frame may have a uniform cross-section shape, and since the productivity of the horizontal frame 64 and the vertical frame is improved and the volume thereof is decreased, material costs may be reduced, and thereby it is possible to reduce costs. Further, poor appearance such as impairment of appearance caused by that the shape of a thick portion is reflected, or the like may be suppressed. Since thickening measures of the horizontal frame 64 and the vertical frame are not required, it is possible to achieve narrowing of the frame, and since the connector 67 abuts the end edge covering part 64a, it is possible to decrease the set thickness more than in Embodiment 1.

### Embodiment 3

A TV receiver according to Embodiment 3 of the present invention has the same configuration as the TV receiver 1 according to Embodiment 1, except that the structure of a connector 80 is different therefrom.

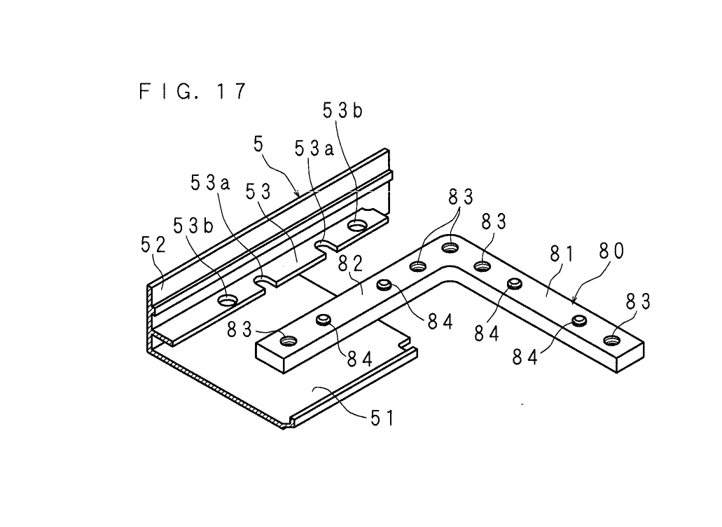

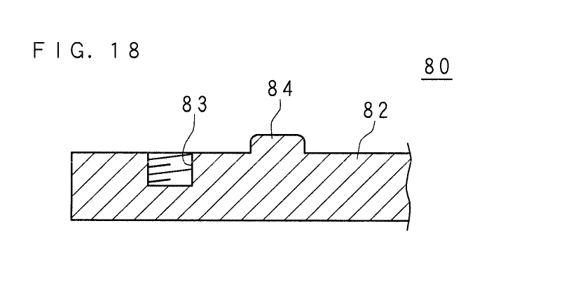

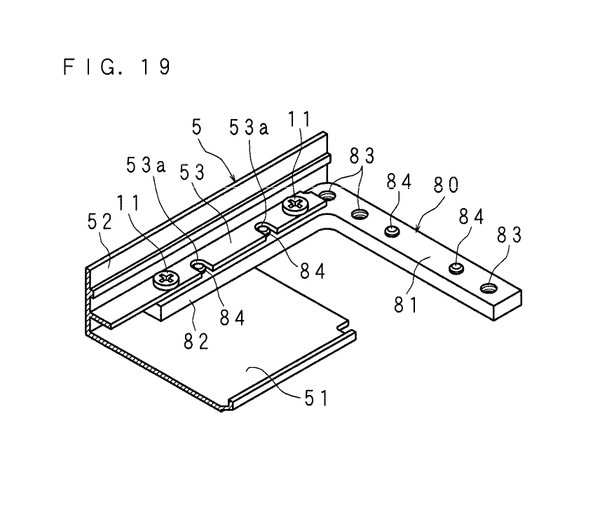

FIG. 17 is a perspective view illustrating a state in which a second plate part 82 of the connector 80 according to Embodiment 3 of the present invention is inserted between the protruding part 53 and the end edge covering part 51 of the vertical frame 5, FIG. 18 is a partial cross-sectional view of the second plate part 82, and FIG. 19 is a perspective view illustrating a state in which the protruding part 53 is screwed to the second plate part 72. In the drawings, the same parts as FIGS. 12 and 13 will be denoted by the same reference numerals, and will not be described.

The connector 80 according to Embodiment 3 is made of stainless steel, and formed in an L shape. A first plate part 81 and the second plate part 82 forming each side of the L shape are different from the connector 7 having a U-shaped cross-section in the short direction, with no recess, and are formed in a square plate shape having a uniform thickness.

The connector 80 is provided with a female screw 83 formed at a corner of an L shape. Further, the first plate part 81 and the second plate part 82 are provided with female screws 83 and 83 respectively formed at portions slightly near the tip end from the corner female screw 83, and female screws 83 and 83 respectively formed at the tip end portions. The female screw 83 is formed so that screw cutting is not performed to a rear side of the connector 80, in a state of being stopped at a middle portion of the connector, that is, does not penetrate the connector 80.

The first plate part 81 and the second plate part 82 are provided with small disc-shaped projections 84 and 84 respectively formed at portions slightly near the tip end from the female screws 83 adjacent to the corner female screw 83. Similarly, the first plate part 81 and the second plate part 82 are provided with projections 84 and 84 respectively formed at portions slightly near the corner from the tip end side female screws 83.

When connecting the connector 80 and the vertical frame 5, first, the second plate part 82 is inserted between the protruding part 53 and the end edge covering part 51 in such a manner that the projections 84 and 84 of the second plate part 82 of the connector 80 are engaged into the notches 53a and 53a of the protruding part 53.

Then, with the projections 84 and 84 locked to the notches 53a and 53a to be fixed (positioned) thereto, the screws 11 and 11 are inserted into the screw insertion holes 53b and 53b, and screwed to two female screws 83 and 83 of the second plate part 82, and thereby the vertical frame 5 and the connector 80 are connected to each other.

The first plate part 81 of the connector 80 is connected to the horizontal frame 4 in the same manner as described above, and the horizontal frame 4 and the vertical frame 5 are finally connected to each other.

In the present embodiment, as described above, since the female screw 83 is only formed to the middle portion of the connector 80 in a thickness direction, when the screw 11 is fastened to the female screw 83, chips generated between the screw 11 and the connector 80 may not dropped to the rear side of the connector 80. A clearance is present between the display panel 21 and an optical member such as the optical sheets 22, or the like (see FIG. 5), however, a decrease in optical quality caused by the chips entering into the clearance may be prevented.

### Embodiment 4

A TV receiver according to Embodiment 4 of the present invention has the same configuration as the TV receiver 1 according to Embodiment 1, except that the structure of a connector 90 is different therefrom.

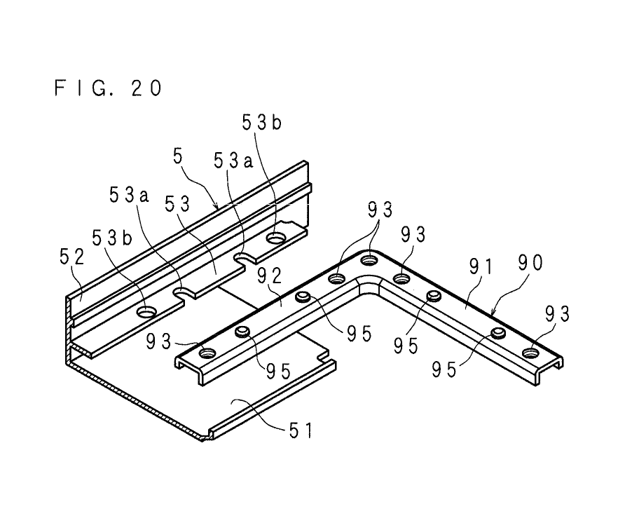

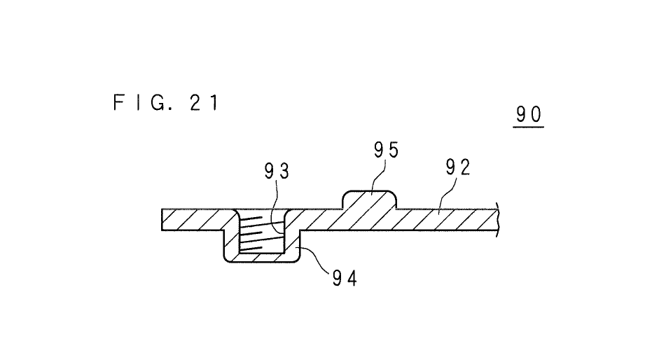

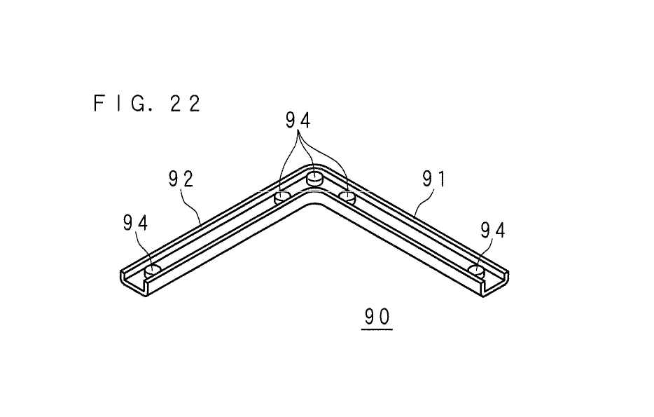

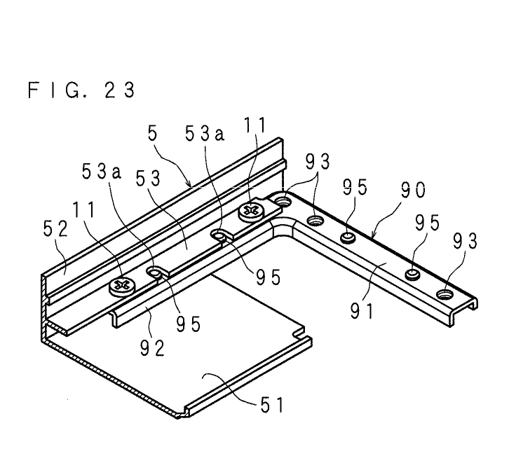

FIG. 20 is a perspective view illustrating a state in which a second plate part 92 of the connector 90 according to Embodiment 4 of the present invention is inserted between the protruding part 53 and the end edge covering part 51 of the vertical frame 5, FIG. 21 is a partial cross-sectional view of the second plate part 92, FIG. 22 is a perspective view illustrating the connector 90 as seen from a back side thereof, and FIG. 23 is a perspective view illustrating a state in which the protruding part 53 is screwed to the second plate part 82. In the drawings, the same parts as FIGS. 12 and 13 will be denoted by the same reference numerals, and will not be described.

The connector 90 according to Embodiment 4 is made of stainless steel, and formed in an L shape. A first plate part 91 and the second plate part 92 forming each side of the L shape are formed in a narrow plate shape, and provided with short legs elongating from opposite end portions thereof in the short side direction. That is, the cross-section thereof is formed in a U shape in the short side direction.

The connector 90 is provided with a female screw 93 formed at a corner of the L shape. Further, the first plate part 91 and the second plate part 92 are provided with female screws 93 and 93 respectively formed at portions slightly near the tip end from the corner female screw 93, and female screws 93 and 93 respectively formed at the tip end portions.

Unlike the connector 7, the female screws 93 are provided in a recessed portions 94 formed by deep drawing from the front side of first plate part 91 and the second plate part 92. The screw detent part 75 which is a screw forming part of the connector 7 is formed in a cylinder shape with no bottom, however, the recessed portion 94 which is a screw forming part of the present embodiment has a bottom portion.

The first plate part 91 and the second plate part 92 are provided with small disc-shaped projections 95 and 95 respectively formed at portions slightly near the tip end from the female screws 93 adjacent to the corner female screw 93. Similarly, the first plate part 91 and the second plate part 92 are provided with projections 95 and 95 respectively formed at portions slightly near the corner from the tip end side female screws 93.

When connecting the connector 90 and the vertical frame 5, first, the second plate part 92 is inserted between the protruding part 53 and the end edge covering part 51 in such a manner that the projections 95 and 95 of the second plate part 92 of the connector 90 are engaged into the notches 53a and 53a of the protruding part 53.

Then, with the projections 95 and 95 locked to the notches 53a and 53a to be fixed (positioned) thereto, the screws 11 and 11 are inserted into the screw insertion holes 53b and 53b, and screwed to two female screws 93 and 93 of the second plate part 92, and thereby the vertical frame 5 and the connector 90 are connected to each other.

The first plate part 91 of the connector 90 is connected to the horizontal frame 4 in the same manner as described above, and the horizontal frame 4 and the vertical frame 5 are finally connected to each other.

In the present embodiment, as described above, since the first plate part 91 and the second plate part 92 are provided with the female screw 93 in the recessed portion 94 formed by the deep drawing, when the screw 11 is fastened to the female screw 93 and chips are generated between the screw 11 and the connector 90, the chips remain in the bottom of the recessed portion 94, and thereby may not dropped to the rear side of the connector 90. Accordingly, a decrease in optical quality caused by the chips entering into the clearance between the display panel 21 and the optical member may be prevented.

As described above, the display device according to the present invention includes a display unit (2), and a rectangular frame (3) covering peripheral edge parts of the display unit (2), wherein the rectangular frame (3) has four frame members (4, 5 and 64) which form respective sides of a rectangle, and the four connectors (7, 67, 80 and 90) which connect adjacent end portions of the four frame members (4, 5 and 64), wherein the connectors (7, 67, 80 and 90) may be provided with female screws (73, 67a, 83 and 93) for screwing with the frame members (4, 5 and 64).

According to the present invention, since the female screws (73, 67a, 83 and 93) are provided in the connectors (7, 67, 80 and 90) using a harder metal than the frame (3), occurrence of defective products due to fastening defect such as screw damage, or the like may be suppressed, and even when replacement of the connector is required due to occurrence of the screw damage, only the connectors (7, 67, 80 and 90) with the damaged screw may be replaced, and therefore replacement costs (F costs) may be reduced.

In addition, torque management of the connecting portion may be made common with the torque management of other general parts made of metal, and therefore productivity and workability may be improved.

Further, the length of the screws (11) may be shortened, and the set thickness may be reduced by arranging the connectors (7, 67, 80 and 90) closer to the frame (3) side. Furthermore, since thickening measures of the frame (3) is not required, it is possible to achieve narrowing of the frame.

In addition, the frame (3) may have a uniform cross-section shape, and since the productivity of the frame (3) is improved and the volume thereof is decreased, material costs may be reduced, and thereby overall cost may be reduced. Further, poor appearance such as impairment of appearance caused by that the shape of a thick portion is reflected, or the like may be suppressed, while having excellent appearance quality.

In the display device according to the present invention, the connectors (7, 67, 80 and 90) may have two plate parts (71, 72, 81, 82, 91 and 92) extending in respective longitudinal directions of each of the frame members (4, 5 and 64) to be connected, and the plate parts (71, 72, 81, 82, 91 and 92) may be provided with the female screws (73, 67a, 83 and 93).

According to the present invention, it is possible to reliably fix by simple structure, and narrow the frame of the display device.

In the display device according to the present invention, the frame members (4, 5 and 64) may have end edge covering parts (41, 51 and 64a) which cover end edge parts of a front surface of the display unit (2) for displaying an image, and side covering parts (42, 52 and 64b) which cover side parts of the display unit, wherein the side covering parts (42, 52 and 64b) may be provided with protruding parts (43 and 53) which protrude substantially parallel to the end edge covering parts (41, 51 and 64a) on the inward sides, the protruding parts (43 and 53) may be provided with insertion holes (43b and 53b) into which screws are inserted, and the plate parts (71, 72, 81, 82, 91, and 92) may be configured to be inserted between the protruding parts (43 and 53) and the end edge covering parts (41 and 51) so that the protruding parts (43 and 53) are screwed to the plate parts (71, 72, 81, 82, 91 and 92).

According to the present invention, it is possible to further decrease the thickness (set thickness) of the front cabinet in front and back direction.

In the display device according to the present invention, the plate parts (71, 72, 91 and 92) may have U-shaped cross-sections in the short side direction.

According to the present invention, the strength of the frame (3) may be secured, and the display device may be lightened.

In the display device according to the present invention, the plate parts (71, 72, 81, 82, 91 and 92) may be provided with projections (74, 84 and 95) on their planes, and the protruding parts (43 and 53) may be provided with locking parts (43a and 53a) for locking the protruding parts (74 84 and 95).

According to the present invention, the frame (3) may be fixed (positioned) to the connectors (7, 80 and 90) and screwed thereto.

In the display device according to the present invention, the female screw (83) may be formed so as not to penetrate the connector (80).

According to the present invention, since the screw cutting is not performed to the rear side of the connector (80), and stopped at the middle portion of the connector (80), when the screw (11) is fastened to the female screw (83) and chips are generated between the screw (11) and the connector (80), the chips may not dropped to the rear side of the connector (80). Therefore, a decrease in optical quality caused by entering the chips between the liquid crystal display panel (21) and the optical member (22) may be prevented.

In the display device according to the present invention, the female screw (93) may be provided in a recessed part (94) formed by the deep drawing from a front side of the connector (90).

According to the present invention, since the connector (90) is provided with the female screw (93) in the recessed portion (94) formed by the deep drawing, when the screw (11) is fastened to the female screw (93) and chips are generated between the screw (11) and the connector (90), the chips remain in the bottom of the recessed portion (94), and thereby may not dropped to the rear side of the connector (90). Accordingly, a decrease in optical quality caused by the chips entering into the clearance between the display panel (21) and the optical member (22) may be prevented.

The television receiver (1, 60) according to the present invention may include: the above-described display device; and a receiving part (12) which receives television broadcast, wherein the display device is configured to display an image based on the television broadcast received by the receiving part (12).

According to the present invention, any one of the above-described display device displays an image thereon based on the television broadcast.

As this description may be embodied in several forms without departing from the spirit of essential characteristics thereof, the present embodiment is therefore illustrative and not restrictive, since the scope is defined by the appended claims rather than by the description preceding them, and all changes that fall within metes and bounds of the claims, or equivalence of such metes and bounds thereof are therefore intended to be embraced by the claims.

1-8. (canceled)

9. A display device which comprises a display unit, and a rectangular frame covering the peripheral edge part of the display unit, wherein the frame has a plurality of frame members which form a plurality of sides of a rectangle, and a plurality of connectors which connect adjacent end portions of the frame members,
wherein the connector is provided with female screws for screwing the frame members.

10. The display device according to claim 9, wherein the connector has two plate parts extending in respective longitudinal directions of the frame members to be connected, and the plate parts are provided with the female screws.

11. The display device according to claim 10, wherein the frame member has an end edge covering part which covers an end edge part of a front surface of the display unit for displaying an image, and a side covering part which covers a side part of the display unit,
the side covering part has a protruding part which protrudes substantially parallel to the end edge covering part on the inward side,
the protruding part is provided with an insertion hole into which a screw is inserted, and
the plate part is configured to be inserted between the protruding part and the end edge covering part so that the protruding part is screwed to the plate part.

12. The display device according to claim 11, wherein the plate part has a U-shaped cross-section in the short side direction.

13. The display device according to claim 11, wherein the plate part is provided with a projection on its plane, and
the protruding part is provided with a locking part for locking the projection.

14. The display device according to claim 12, wherein the plate part is provided with a projection on its plane, and
the protruding part is provided with a locking part for locking the projection.

15. The display device according to claim 11, wherein the female screw is formed so as not to penetrate the connector.

16. The display device according to claim 13, wherein the female screw is formed so as not to penetrate the connector.

17. The display device according to claim 11, wherein the female screw is provided in a recessed part formed by deep drawing from a front side of the connector.

18. The display device according to claim 12, wherein the female screw is provided in a recessed part formed by deep drawing from a front side of the connector.

19. The display device according to claim 13, wherein the female screw is provided in a recessed part formed by deep drawing from a front side of the connector.

20. The display device according to claim 14, wherein the female screw is provided in a recessed part formed by deep drawing from a front side of the connector.

21. A television receiver comprising:
the display device according to claim 11; and
a receiving part which receives a television broadcast,
wherein the display device is configured to display an image based on the television broadcast received by the receiving part.

22. A television receiver comprising:
the display device according to claim 12; and
a receiving part which receives a television broadcast,
wherein the display device is configured to display an image based on the television broadcast received by the receiving part.

23. A television receiver comprising:
the display device according to claim 13; and
a receiving part which receives a television broadcast,
wherein the display device is configured to display an image based on the television broadcast received by the receiving part.

24. A television receiver comprising:
the display device according to claim 14; and
a receiving part which receives a television broadcast,
wherein the display device is configured to display an image based on the television broadcast received by the receiving part.

25. A television receiver comprising:
the display device according to claim 15; and
a receiving part which receives a television broadcast,
wherein the display device is configured to display an image based on the television broadcast received by the receiving part.

26. A television receiver comprising:
the display device according to claim 16; and
a receiving part which receives a television broadcast,
wherein the display device is configured to display an image based on the television broadcast received by the receiving part.

27. A television receiver comprising:
the display device according to claim 17; and
a receiving part which receives a television broadcast,
wherein the display device is configured to display an image based on the television broadcast received by the receiving part.

28. A television receiver comprising:
the display device according to claim 18; and
a receiving part which receives a television broadcast,
wherein the display device is configured to display an image based on the television broadcast received by the receiving part.
